(19) United States
(12) Patent Application Publication
(10) Pub. No.: US 2026/0150700 A1
(43) Pub. Date: May 28, 2026

(54) USING ELECTRICAL CURRENT MEASUREMENT TO DETERMINE ALIGNMENT OF INTEGRATED CIRCUIT STRUCTURES DURING BONDING

(71) Applicant: Taiwan Semiconductor Manufacturing Company, Ltd., Hsin-Chu (TW)

(72) Inventors: Yung-Ta Chen, Taichung City (TW); Che Chi Shih, Hsinchu City (TW); Jin-Hao Jhang, Hsinchu County (TW)

(21) Appl. No.: 19/080,172

(22) Filed: Mar. 14, 2025

Related U.S. Application Data
(60) Provisional application No. 63/725,435, filed on Nov. 26, 2024.

(51) Int. Cl. H01L 23/544; H01L 23/00; H10D 84/85

(52) U.S. Cl. CPC H10W 46/00; H10D 84/851; H10W 46/301; H10W 72/07223; H10W 72/07231; H10W 90/792

(57) ABSTRACT

A first bonding structure is positioned with respect to a second bonding structure. The first bonding structure includes a first alignment component. The second bonding structure includes a second alignment component that faces toward the first alignment component in a vertical direction. A relative position between the first alignment component and the second alignment component is shifted in at least a first horizontal direction while the first alignment component and the second alignment component. An electrical current is measured through the first alignment component and the second alignment component while the relative position between the first alignment component and the second alignment component is shifted in the first horizontal direction. The first bonding structure is bonded to the second bonding structure based on a result of the measuring of the electrical current.

### PRIORITY DATA

The present application is a utility U.S. application of provisional U.S. application No. 63/725,435, filed on Nov. 26, 2024, entitled “Electric Assisted High Accuracy Alignment for Hybrid Bonding”, the disclosure of which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs. For example, as device sizes shrink, bonding alignment between different devices becomes more difficult. If devices are bonded but not aligned well, the device performance may not be optimal.

Therefore, although conventional methods of bonding IC structures have generally been adequate, they have not been entirely satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a perspective view of an IC device in the form of a FinFET according to various aspects of the present disclosure.

FIG. 1B is a planar top view of an IC device in the form of a FinFET according to various aspects of the present disclosure.

FIG. 1C is a cross-sectional side view of an IC device in the form of a GAA device according to various aspects of the present disclosure.

FIG. 1D is a cross-sectional side view of a portion of a complementary field effect transistor (CFET) according to various aspects of the present disclosure.

FIGS. 2-3, 4-4A, and 5-10 illustrate cross-sectional side views of IC structures undergoing a bonding process according to various aspects of the present disclosure.

FIG. 11 is a graph illustrating a relationship between relative lateral position and electrical current according to various aspects of the present disclosure.

FIG. 12 illustrates a cross-sectional side view two IC structures that are bonded together according to various aspects of the present disclosure.

FIGS. 13A and 13B illustrate cross-sectional side views of IC structures that can be bonded together under different bonding schemes according to various aspects of the present disclosure.

FIG. 14 is a block diagram of an IC fabrication facility according to various aspects of the present disclosure.

FIG. 15 is a flowchart illustrating a method of bonding IC devices according to various aspects of the present disclosure.

FIG. 16 is a flowchart illustrating a method of bonding IC devices according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc., as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to semiconductor devices, and more particularly, to the bonding alignment of IC structures that include field-effect transistors (FETs), such as three-dimensional fin-shaped FETs (FinFETs) or gate-all-around (GAA) devices. In that regard, a FinFET device is a fin-like field-effect transistor device, and a GAA device is a multi-channel field-effect transistor device. FinFET devices and GAA devices have both been gaining popularity recently in the semiconductor industry, since they offer several advantages over traditional Metal-Oxide Semiconductor Field Effect Transistor (MOSFET) devices (e.g., “planar” transistor devices). These advantages may include better chip area efficiency, improved carrier mobility, and fabrication processing that is compatible with the fabrication processing of planar devices. Thus, it may be desirable to design an integrated circuit (IC) chip using FinFET devices or GAA devices for a portion of, or the entire IC chip.

However, in spite of the advantages offered by the FinFET devices and/or GAA devices, certain challenges may still remain in IC applications in which FinFET or GAA devices are implemented. For instance, modern manufacturing of ICs may entail bonding different IC structures together. However, as device sizes get scaled down, alignment between different IC structures may become more difficult. If devices are bonded but not aligned well, then device performance may be sub-optimal.

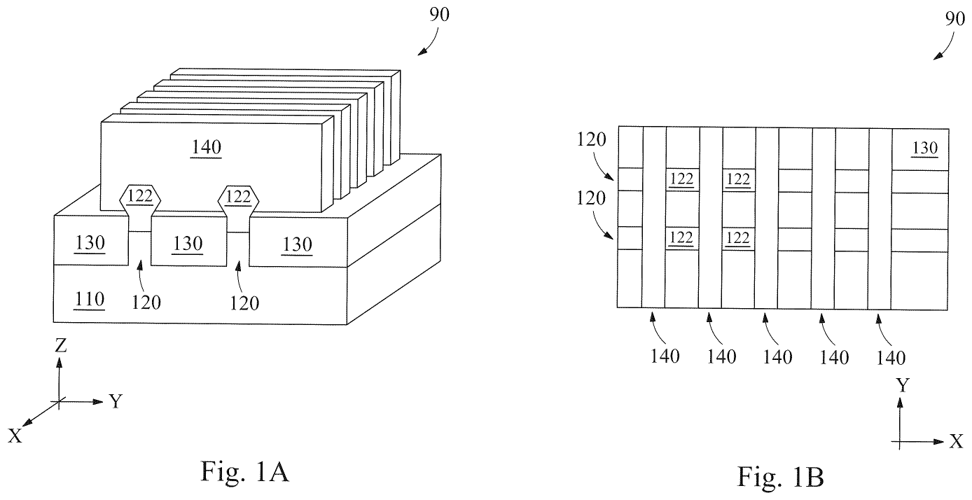

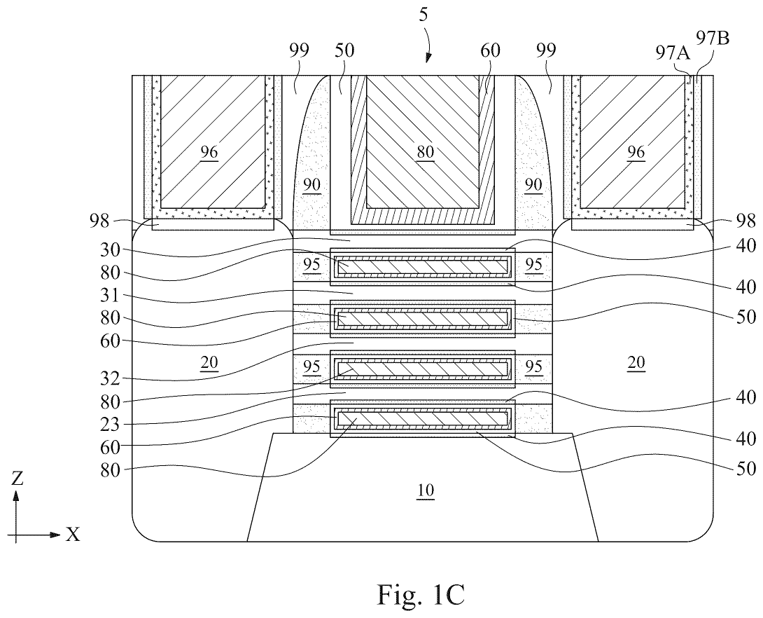

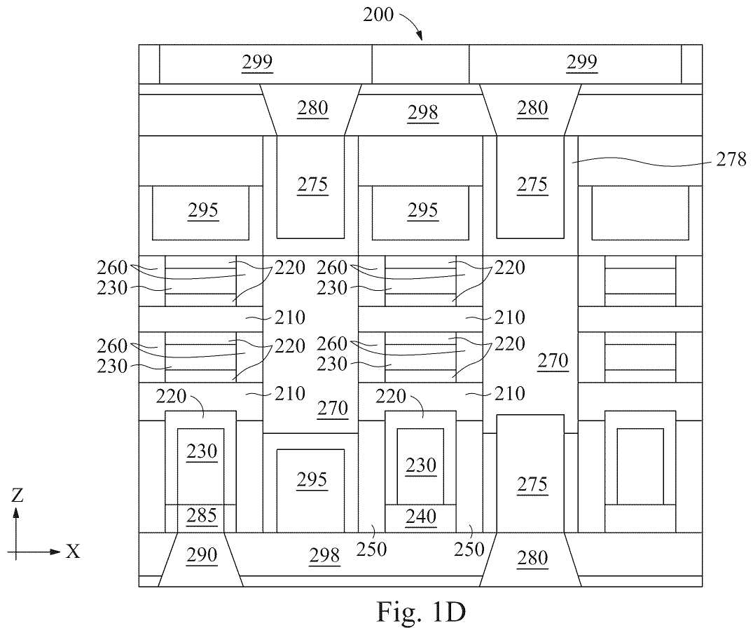

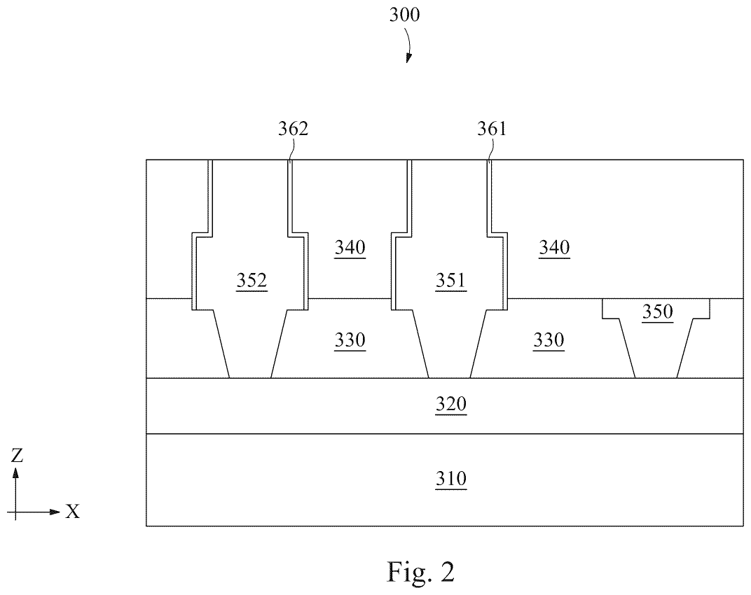

To address the issues discussed above, the present disclosure implements an electric assisted alignment scheme to improve the bonding alignment between different IC structures. In that regard, FIGS. 1A-1D illustrate example types of transistors that may be the subject of IC device bonding, and FIGS. 2-16 illustrate the various aspects of the bonding alignment scheme, as discussed below in more detail.

Referring now to FIGS. 1A-1D, these figures describe the basic structures of example FinFET and GAA devices. For example, FIGS. 1A and 1B illustrate a three-dimensional perspective view and a top view of a portion of an Integrated Circuit (IC) device 90, respectively. The IC device 90 may be an intermediate device fabricated during processing of an IC, or a portion thereof, that may comprise static random-access memory (SRAM) and/or other logic circuits, passive components such as resistors, capacitors, and inductors, and active components such as p-type FETs (PFETs), n-type FETs (NFETs), FinFETs, metal-oxide semiconductor field effect transistors (MOSFET), complementary metal-oxide semiconductor (CMOS) transistors, bipolar transistors, high voltage transistors, high frequency transistors, and/or other memory cells. Note that the present disclosure is not limited to any particular number of devices or device regions, or to any particular device configurations, unless otherwise claimed. For example, although the IC device 90 as illustrated is a three-dimensional FinFET device, the concepts of the present disclosure may also apply to planar FET devices or GAA devices.

Referring to FIG. 1A, the IC device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions 120 are formed on the substrate 110. The active regions 120 are elongated fin-like structures that protrude upwardly out of the substrate 110. As such, the active regions 120 may be interchangeably referred to as fin structures 120 hereinafter. The fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain features 122 formed over the fin structures 120. The source/drain features 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fin structures 120 on three sides in a channel region of each fin 120. The gate structures 140 may be dummy gate structures (e.g., containing an oxide gate dielectric and a polysilicon gate electrode), or they may be HKMG structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIG. 1B, multiple fin structures 120 are oriented lengthwise along the X-direction, and multiple gate structures 140 are oriented lengthwise along the Y-direction, i.e., generally perpendicular to the fin structures 120. In many embodiments, the IC device 90 includes additional features such as gate spacers disposed along sidewalls of the gate structures 140, hard mask layer(s) disposed over the gate structures 140, and numerous other features.

It is also understood that the various aspects of the present disclosure discussed below may apply to multi-channel devices such as Gate-All-Around (GAA) devices. FIG. 1C illustrates a diagrammatic cross-sectional side view of a portion of an IC device 5 fabricated according to embodiments of the present disclosure, where the IC device 5 is a gate-all-around (GAA) device and may be referred to as a GAA device 5 hereinafter. It is understood that the GAA device 5 may be an NFET in some embodiments, or it may be a PFET in other embodiments.

Referring to FIG. 1C, the cross-sectional view of the GAA device 5 is taken along an X-Z plane, where the X-direction (same X-direction as in FIG. 1A) is the horizontal direction, and the Z-direction (same Z-direction as in FIG. 1A) is the vertical direction. The GAA device 5 includes a fin structure 10, which may be similar to the fin structure 120 discussed above. In some embodiments, the fin structure 10 includes silicon. The GAA device 5 includes source/drain features 20, which may be similar to the source/drain features 122 discussed above. In embodiments where the GAA device 5 is an NFET, the source/drain features 20 include silicon phosphorous (SiP). In embodiments where the GAA device 5 is a PFET, the source/drain features 20 include silicon germanium (SiGe).

The GAA device 5 includes a plurality of channels, for example channels 30-33 as shown in FIG. 1C. The channels 30-33 each include a semiconductive material, for example silicon or a silicon compound. The channels 30-33 are nanostructures (e.g., having sizes that are in a range of a few nanometers) and may also each have an elongated shape and extend in the X-direction. In some embodiments, the channels 30-33 may each have a nano-wire shape, a nano-sheet shape, a nano-tube shape, etc. The cross-sectional profile of the nano-wire, nano-sheet, or nano-tube may be round/circular, square, rectangular, hexagonal, elliptical, or combinations thereof.

In some embodiments, the lengths (e.g., measured in the X-direction) of the channels 30-33 may be different from each other. For example, a length of the channel 30 may be less than a length of the channel 31, which may be less than a length of the channel 32, which may be less than a length of the channel 33. In some embodiments, each of the channels 30-33 may not have uniform thicknesses.

In some embodiments, a spacing (e.g., measured in the Z-direction) between the channels 30-33 (each channel from adjacent channels) is in a range between about nanometers (nm) and about 12 nm. In some embodiments, a thickness (e.g., measured in the Z-direction) of each of the channels 30-33 is in a range between about 5 nm and about nm. In some embodiments, a width (e.g., measured in the Y-direction of FIG. 1A) of each of the channels 30-33 is in a range between about 15 nm and about 150 nm. A plurality of interfacial layers (ILs) 40 may also be formed on the upper and lower surfaces of the channels 30-33.

The GAA device 5 also includes gate structures that are disposed over and in between the channels 30-33. The gate structures may include gate dielectric layers 50. In some embodiments, the gate dielectric layers 50 include a high-k gate dielectric. The gate structures further include one or more work function metal layers 60. In embodiments where the GAA device 5 is an NFET, the one or more work function metal layers 60 include N-type work function metal layers, such as TiAlC. In embodiments where the GAA device 5 is a PFET, the one or more work function metal layers 60 include P-type work function metal layers, such as TiN.

The gate structures also include fill metals 80. In the portion of the gate structure formed over the channels 30-33, the fill metal 80 are formed over the one or more work function metal layers 60. The one or more work function metal layers 60 have a U-shape and wrap around the fill metal 80, and the gate dielectric layer 50 also has a U-shape and wrap around the one or more work function metal layers 60. In portions of the gate structures formed between the channels 30-33, the fill metal 80 is circumferentially surrounded (in the cross-sectional view) by the one or more work function metal layers 60, which is then circumferentially surrounded by the gate dielectric layer 50. It is understood that the gate structures may also include a glue layer that is formed between the one or more work function metal layers 60 and the fill metal 80 to increase adhesion. However, for reasons of simplicity, such a glue layer is not specifically illustrated herein.

The GAA device 5 also includes gate spacers 90 and inner spacers 95 that are disposed on sidewalls of the gate dielectric layer 50. The inner spacers 95 are also disposed between the channels 30-33. The gate spacers and the inner spacers 95 may include a dielectric material, for example a low-k material such as SiOCN, SiON, SiN, or SiOC.

The GAA device 5 further includes source/drain contacts 96 that are formed over the source/drain features 20. The source/drain contacts 96 may include a conductive material such as cobalt, copper, aluminum, tungsten, or combinations thereof. The source/drain contacts 96 are surrounded by barrier layers, for example barrier layers 97A and 97B, which help prevent or reduce diffusion of materials from and into the source/drain contacts 96. In some embodiments, the barrier layer 97A includes TiN, and the barrier layer 97B includes SiN. A silicide layer 98 may also be formed between the source/drain features 20 and the source/drain contacts 96, so as to reduce the source/drain contact resistance. The silicide layer 98 may contain a metal silicide material, such as cobalt silicide in some embodiments.

The GAA device 5 further includes an interlayer dielectric (ILD) 99. The ILD 99 provides electrical isolation between the various components of the GAA device 5, for example between the gate structures and the source/drain contacts 96.

GAA devices may also offer advantages such as better chip area efficiency, improved carrier mobility, etc. As such, advanced IC chips may be implemented using the GAA devices as well. However, it is understood that the present disclosure is not limited to any particular number of devices or device regions, or to any particular device configurations, unless otherwise claimed. For example, although FinFET devices or GAA devices have been described as potential transistors that could be used to implement the IC chip or a portion thereof, the concepts of the present disclosure discussed in more detail below may also apply to IC chips implemented using planar FET devices as well.

FIG. 1D is a cross-sectional side view of a portion of a complementary field effect transistor (CFET) 200 illustrated along an X-Z plane. In some embodiments, the illustrated portion of the CFET 200 is a top tier device, which may include one or more GAA transistors (similar to the GAA device 5 discussed above with reference to FIG. 1C). The top tier device may be bonded to a bottom tier deice of the CFET in a bonding process of the present disclosure discussed below. It is understood, however, that the top tier device and the bottom tier device may have substantially similar or even identical structures in some embodiments. In other embodiments, the top tier device may include n-type transistors, while the bottom tier device may include p-type transistors, or vice versa, but the rest of their respective device configurations may be substantially similar or identical. In any case, it is understood that the descriptions of the top tier device of the CFET 200 may apply to the bottom tier device as well, unless otherwise noted.

Referring to FIG. 1D, the portion of the CFET 200 includes a plurality of semiconductor layers, such as the semiconductor layers 210. The semiconductor layers 210 may be disposed vertically over one another in a stack, and collectively they may serve as the channel components of a GAA transistor of the portion of the CFET 200. In some embodiments, the semiconductor layers 210 each include silicon. In other embodiments, the semiconductor layers 210 may include another suitable type of semiconductor material.

The portion of the CFET 200 further includes a plurality of gate dielectric layers, such as gate dielectric layers 220. In some embodiments, the gate dielectric layers 220 each include a high-k dielectric layer, which may be a dielectric material having a dielectric constant that is greater than a dielectric constant of silicon dioxide (k≈3.9). For example, the high-k dielectric layer may be implemented using as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si₃N₄, HfO₂—Al₂O₃, or a combination thereof. In the illustrated embodiment, the gate dielectric layers 220 may include a hafnium-based oxide (e.g., HfO₂) layer and/or a zirconium-based oxide (e.g., ZrO₂) layer. It is understood that the gate dielectric layers 220 may further include an interfacial layer that includes a dielectric material, such as SiO₂, SiGeOₓ, HfSiO, SiON, other dielectric material, or a combination thereof.

The portion of the CFET 200 further includes a plurality of gate electrode layers, such as gate electrode layers 230. The gate electrode layers 230 are formed on the gate dielectric layers 220 and include an electrically conductive material, such as Al, Cu, Ti, Ta, W, Mo, Co, TaN, NiSi, CoSi, TiN, WN, TiAl, TiAlN, TaCN, TaC, TaSiN, or a combination thereof. In some embodiments, the gate electrode layers 230 each include a work function layer and a fill-metal layer. The work function layer is an electrically conductive layer tuned to have a desired work function, such as an n-type work function or a p-type work function. The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or a combination thereof. Meanwhile, the fill metal layer is an electrically conductive bulk layer formed over the work function layer, and it may include materials such as Al, W, Cu, Ti, Ta, TiN, TaN, polysilicon, alloys thereof, or a combination thereof. In some embodiments, the gate electrode layers 230 may further include a barrier (blocking) layer. The barrier layer includes a material that prevents or eliminates diffusion and/or reaction of constituents between adjacent layers and/or promotes adhesion between adjacent layers, such as between the work function layer and the fill-metal layer. In some embodiments, the barrier layer includes metal and nitrogen, such as titanium nitride, tantalum nitride, tungsten nitride (e.g., W₂N), titanium silicon nitride (TiSiN), tantalum silicon nitride (TaSiN), or a combination thereof.

The gate dielectric layers 220 and the gate electrode layers 230 may be formed by a gate replacement process, in which dummy gate structures are replaced by functional gate structures that comprise the gate dielectric layers 220 and the gate electrode layers 230. The location and/or the dimensions of the dummy gate structures (and therefore the functional gate structures) may be defined at least in part by hard mask layers 240, which may include a dielectric material such as silicon nitride, silicon oxynitride, silicon carbide, silicon oxycarbide, silicon carbonitride, silicon oxycarbonitride, or a combination thereof. In some other embodiments, the hard mask layer 240 may include metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HFO₂), zirconium aluminum oxide (e.g., ZrAlO), or a combination thereof. It is understood that a gate stack (or a gate structure) may be formed by the gate dielectric layers 220 and the gate electrode layers 230.

Gate spacers 250 are disposed along sidewalls of the portions of the gate stack disposed immediately adjacent to the hard mask layer 240, and inner spacers 260 are disposed along sidewalls of the other portions of the gate stack. The gate spacers 250 and the inner spacers 260 may include dielectric materials such as silicon oxide, silicon nitride, silicon oxynitride, silicon carbide, silicon carbonitride, silicon oxycarbide, silicon oxycarbonitride, or a combination thereof, though it is understood that the gate spacers 250 and the inner spacers 260 may include different types of materials and/or different configurations (e.g., different numbers of layers). For example, in some embodiments, the gate spacers 250 may include more than one set of spacers, such as seal spacers, offset spacers, sacrificial spacers, dummy spacers, main spacers, or a combination thereof. The various sets of spacers may have different compositions.

The portion of the CFET 200 further includes a plurality of source/drain regions 270 disposed on opposite sides of the gate stack. The source/drain regions 270 may be epitaxially grown, and they may be doped with n-type dopants and/or p-type dopants. For example, the source/drain regions 270 may include silicon that may be doped with carbon, phosphorous, arsenic, other n-type dopant, or a combination thereof (e.g., Si:C epitaxial source/drains, Si:P epitaxial source/drains, or Si:C:P epitaxial source/drains). As another example, the source/drain regions 270 may include silicon germanium or germanium that is doped with boron, other p-type dopant, or a combination thereof (e.g., Si:Ge:B epitaxial source/drains). The source/drain regions 270 may also include materials and/or dopants that achieve desired tensile stress and/or compressive stress in adjacent channel regions (e.g., formed by semiconductor layers 210). As used herein, the source/drain region 270 may refer to a source of a device (e.g., a particular transistor), a drain of a device, or a source and/or a drain of multiple devices.

The portion of the CFET 200 also includes source/drain contacts, such as source/drain contacts 275, that are disposed vertically above or below the source/drain regions 270 to provide electrical connectivity to the source/drain regions 270. In some embodiments, at least some of the source/drain contacts 275 may be at least partially surrounded by barrier layers or liner layers 278.

The portion of the CFET 200 may further include conductive vias, such as conductive vias 280, that are disposed vertically above or below the source/drain contacts 275, to further provide electrical connectivity to the source/drain contacts 275, and by extension, to the source/drain regions 270. The portion of the CFET 200 may further include gate contacts, such as gate contact 285, as well as conductive vias, such as conductive via 290, that are configured to provide electrical connectivity to particular gate structures. The source/drain contacts 275, the gate contacts 285, and the conductive vias 280 and 290 may each include one or more types of conductive materials, such as tungsten, aluminum, copper, cobalt, ruthenium, and/or combinations thereof.

The portion of the CFET 200 may also include electrical isolation layers/structures that are configured to provide electrical isolation among various microelectronic components (e.g., the gate electrode layers 230 or the source/drain regions 270). For example, the portion of the CFET 200 may include an interlayer dielectric (ILD) 295 and one or more dielectric layers 298. For example, the ILD and/or the dielectric layers 298 may include dielectric materials such as silicon oxide, carbon doped silicon oxide, silicon nitride, silicon oxynitride, tetraethyl orthosilicate (TEOS)-formed oxide, boron silicate glass (BSG), phosphosilicate glass (PSG), borophosphosilicate glass (BPSG), fluorosilicate glass (FSG), xerogel, aerogel, amorphous fluorinated carbon, parylene, benzocyclobutene-based (BCB) material, polyimide, other dielectric material, or a combination thereof. The ILD 295 may also be surrounded by a contact etching stop layer (CESL), which may have a different material composition than the ILD 295.

The portion of the CFET 200 may also include bonding pads 299. The bonding pads 299 may include a conductive material, such as Al, Ag, Au, Cu, Co, Ir, Mo, Ni, Pt, Ru, Si, Ta, Tu, W, Zr, or a combination thereof. The bonding pads 299 may each be electrically coupled to one or more other conductive components, such as the conductive vias 280. As such, the bonding pads 299 may be utilized to provide electrical connectivity to the microelectronic components of the CFET 200, such as to the source/drain regions 270. Although not specifically illustrated herein for reasons of simplicity, it is understood that bonding pads similar to the bonding pads 299 may be implemented to provide electrical connectivity to the gate structures of the CFET 200 as well.

Other components of the CFET 200 are not specifically discussed herein for reasons of simplicity. It is also understood that in embodiments where the portion of the CFET 200 illustrated in FIG. 1D is a top tier device, then a bottom tier device that has a substantially similar or identical structure as the top tier device may be bonded to the top tier device to form the CFET. In some embodiments, the top tier device may include n-type transistors, while the bottom tier device may include p-type transistors, or vice versa. In other embodiments, the top tier device and the bottom tier device may include the same type of transistors (e.g., both including n-type transistors or both including p-type transistors).

Regardless of whether the transistors of an IC are implemented as a FinFET of FIGS. 1A-1B, as a GAA device of FIG. 1C, or as a CFET device of FIG. 1D, it is understood that they may benefit from the concepts of the present disclosure, as discussed below in more detail.

FIGS. 2-10 and 12 collectively illustrate a series of diagrammatic fragmentary cross-sectional side views (e.g., along the X-Z plane) that correspond to a process flow to bond different IC structures together according to different embodiments of the present disclosure.

Referring now to FIG. 2, an IC structure 300 includes a carrier wafer 310. The carrier wafer may include a silicon wafer in some embodiments or a glass wafer in some other embodiments. The IC structure 300 may also include an IC device 320 that is disposed over the carrier wafer 310. In some embodiments, the IC device 320 may include the portion of the CFET 200 discussed above with reference to FIG. 1D (or a portion thereof), for example, the top tier device of the CFET 200. In other embodiments, the IC device 320 may include the FinFET or GAA devices discussed above with reference to FIGS. 1A-1C (or portions thereof). For reasons of simplicity, the IC device 320 is illustrated herein as a layer, but it is understood that it includes a plurality of microelectronic components of the CFET, FinFET, or GAA device in the corresponding embodiments, such as the channel layers, gate structures, source/drains, and various interconnection components and isolation structures.

The IC structure 300 also includes one or more dielectric layers, such as a dielectric layer 330 disposed over the IC device 320 and a dielectric layer 340 disposed over the dielectric layer 330. In various embodiments, the dielectric layers 330 and 340 may include SiN, SiON, SiCN, SiOC, SiOCN, BN, BCN, TiO₂, TiON, TiN, AlOₓ, AlON, AlN, or a combination thereof. In some embodiments, the dielectric layers 330 or 340 may include portions of the ILD 295 and/or portions of the dielectric layers 298 of the portion of the CFET 200 discussed above with reference to FIG. 1D.

The IC structure 300 also includes a plurality of conductive structures, such as conductive structures 350, 351, and 352, that are formed to extend vertically (e.g., in the Z-direction) through one or more of the dielectric layers 330 and 340. For example, at this stage of fabrication, the conductive structure 350 is formed to extend vertically through just the dielectric layer 330 but not the dielectric layer 340, while the conductive structures 351-352 are formed to extend vertically through both the dielectric layers 330 and 340. In some embodiments, the conductive structures 350-352 may be embodiments of the source/drain contact 275, sourced/drain via 280, gate contact 285, gate via 290, and/or the bonding pads 299 discussed above with reference to FIG. 1D. In various embodiments, one or more of the conductive structures 350-352 may serve as bonding structures in a subsequent fabrication process.

The conductive structures 350-352 may include conductive materials, such as Al, Ag, Au, Cu, Co, Ir, Mo, Ni, Pt, Ru, Si, Ta, Tu, W, Zr, or a combination thereof. In some embodiments, the conductive structures 350-352 may be formed by etching openings in one or more of the dielectric layers 330 and 340 and filling these openings with the conductive materials. In some embodiments, at least the second portion of the conductive structures 351-352 may also include respective liners 361-362 (e.g., as a barrier layer) formed around them, thereby separating them from the dielectric layer 340.

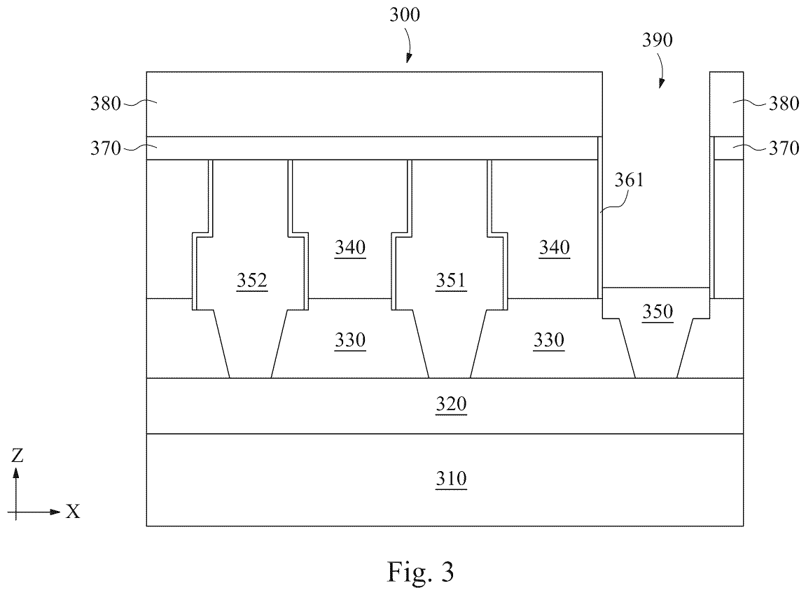

Referring now to FIG. 3, a dielectric layer 370 is formed over the dielectric layer 340 and over the conductive structures 351-352. The dielectric layer 370 may have a different material composition than the dielectric layer 340 in some embodiments. A patterned photoresist layer 380 is then formed over the dielectric layer 370. The patterned photoresist layer 380 may be formed by forming a photoresist material over the dielectric layer 370 via a spin coating process, and then performing a lithography process to pattern the photoresist material. The lithography process may include an exposure step, a post-exposure bake step, a developing step, a post-developing step, etc. The result is the formation of the patterned photoresist layer 380 that includes an opening 390 that is aligned with the conductive structure 350. One or more etching processes are then performed to extend the opening 390 downward vertically until an upper surface 395 of the conductive structure 350 is exposed. The rest of the conductive structures 351-352 are covered by the dielectric layer 370 and/or the patterned photoresist layer 380. Note that a liner 360 may also be formed on the side surfaces of the dielectric layer 340 (e.g., sidewalls of the opening 390) in some embodiments.

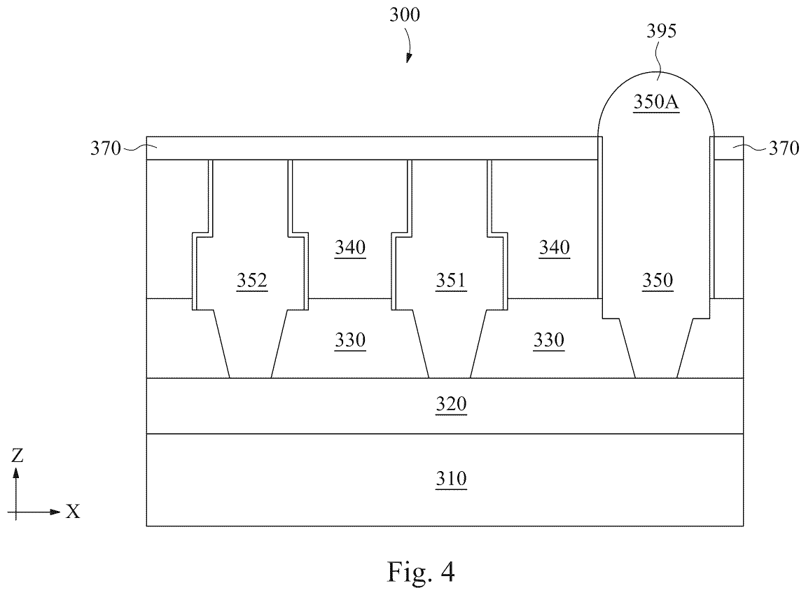

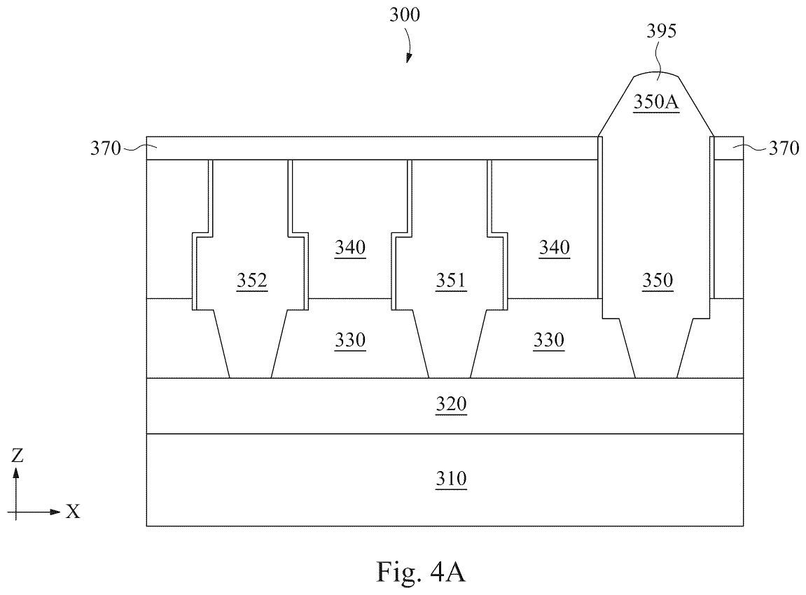

Referring now to FIG. 4, the patterned photoresist layer 380 is removed, for example, via a PR stripping or PR ashing process. Additional processes may then be performed to form a protruding portion 350A of the conductive structure 350. In some embodiments, the additional processes may include a deposition process is performed to deposit an additional conductive material over the conductive structure 350. For example, the deposition process may include a chemical vapor deposition (CVD), a physical vapor deposition (PVD), an atomic layer deposition (ALD), etc. Since the conductive structures 351-352 are covered by the dielectric layer 370, no portion of the conductive material is deposited over the conductive structures 351-352. The deposition processes may be configured such that parts of the conductive structure 350 protrudes over the upper surface of the dielectric layer 370, thereby forming the protruding portion 350A. In some embodiments, the deposition processes may be configured such that the upper surface of the protruding portion 350A has a convex shape and may be at least partially curved.

Referring now to FIG. 4A, the additional processes may also include an optional step to further define the shape of the portion of the protruding portion 350A the conductive structure 350. For example, the optional step may include one or more etching processes, such as etch back processes, to further sharpen the protruding portion 350A. In other words, the optional step may cause the protruding portion 350A to be pointier and/or less rounded in the cross-sectional side view. Regardless of whether the optional step is performed, however, the end result is that the protruding portion 350A still protrudes above (in the Z-direction) the upper surfaces of the dielectric layer 370 (and thus above the upper surfaces of the conductive structures 351-352) as shown in FIGS. 4-4A.

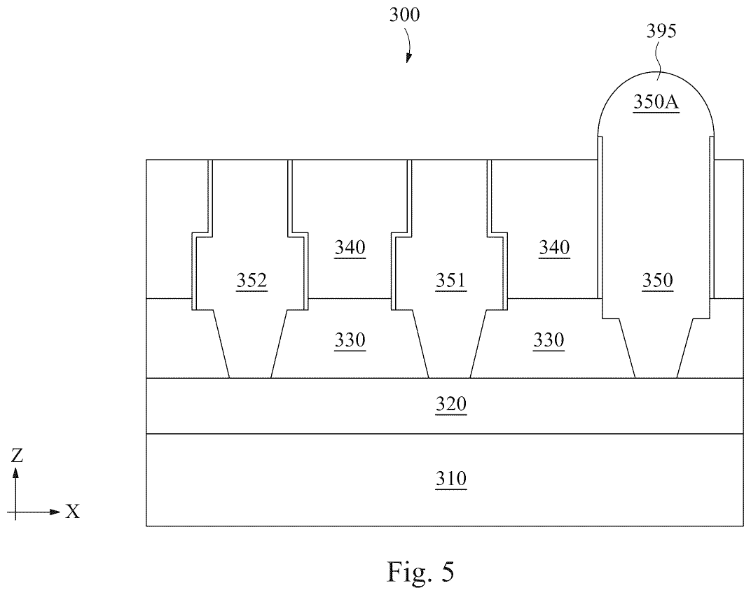

Referring now to FIG. 5, the dielectric layer 370 is removed. At this point, the upper surfaces of the conductive structures 350-352 (including the protruding portion 350A) and the dielectric layer 340 are exposed. As clearly shown in FIG. 5, the protruding portion 350A protrudes well above the upper surfaces of the conductive structures 351-352 and the dielectric layer 340.

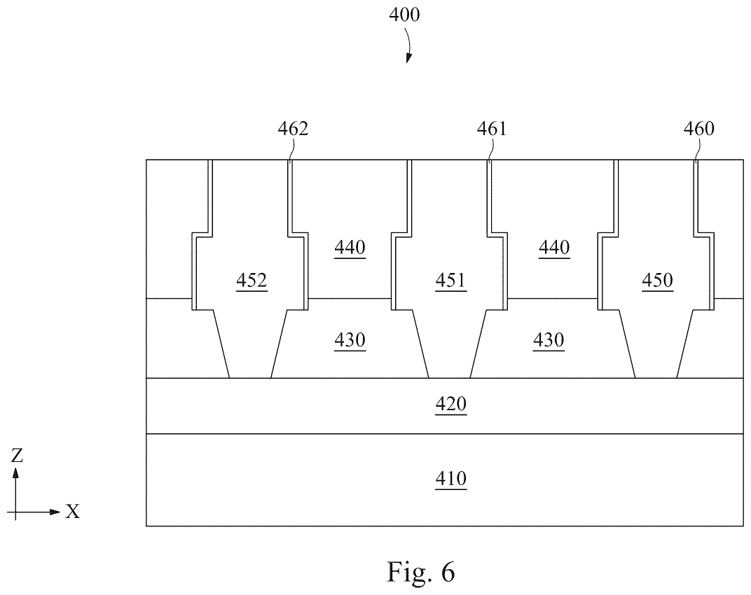

Referring now to FIG. 6, another IC structure 400 is illustrated. The IC structure 400 includes a carrier wafer 410. The carrier wafer may include a silicon wafer in some embodiments or a glass wafer in some other embodiments. The IC structure 400 may also include an IC device 420 that is disposed over the carrier wafer 310. In some embodiments, the IC device 420 may include a device that is substantially similar to the portion of the CFET 200 discussed above with reference to FIG. 1D. For example, the IC device may include a bottom tier device of the CFET 200. Thus, in some embodiments, the IC device 320 may include the top tier device of the CFET 200, and the IC device 320 may include the bottom tier device of the CFET 200, where the top tier device includes p-type transistors, and the bottom tier device includes n-type transistors, or vice versa. In other embodiments, the IC device 420 may include the FinFET or GAA devices discussed above with reference to FIGS. 1A-1C. For reasons of simplicity, the IC device 420 is illustrated herein as a layer, but it is understood that it includes a plurality of microelectronic components of the CFET, FinFET, or GAA device in the corresponding embodiments.

The IC structure 400 also includes one or more dielectric layers, such as a dielectric layer 430 disposed over the IC device 420 and a dielectric layer 440 disposed over the dielectric layer 430. In various embodiments, the dielectric layers 430 and 440 may include SiN, SiON, SiCN, SiOC, SiOCN, BN, BCN, TiO₂, TiON, TiN, AlOₓ, AlON, AlN, or a combination thereof. In some embodiments, the dielectric layers 430 or 440 may include portions of the ILD 295 and/or portions of the dielectric layers 298 of the portion of the CFET 200 discussed above with reference to FIG. 1D.

The IC structure 400 also includes a plurality of conductive structures, such as conductive structures 450, 451, and 452, that are formed to extend vertically (e.g., in the Z-direction) through the dielectric layers 430 and 440. In some embodiments, the conductive structures 450-452 may be embodiments of the source/drain contact 275, sourced/drain via 280, gate contact 285, gate via 290, and/or the bonding pads 299 discussed above with reference to FIG. 1D. In various embodiments, one or more of the conductive structures 450-452 may serve as bonding structures in a subsequent fabrication process.

The conductive structures 450-452 may include conductive materials, such as Al, Ag, Au, Cu, Co, Ir, Mo, Ni, Pt, Ru, Si, Ta, Tu, W, Zr, or a combination thereof. In some embodiments, the conductive structures 450-452 may be formed by etching openings in the dielectric layers 430 and 440 and filling these openings with the conductive materials. In some embodiments, the conductive structures 450-452 may each be formed in multiple stages. For example, a first portion of the conductive structures 450-452 may be formed by etching openings in the dielectric layer 430 and filling the etched openings in the dielectric layer 430 with a conductive material, and a second portion of the conductive structures 450-452 may be formed by etching openings in the dielectric layer 440 and filling the etched openings in the dielectric layer 440 with a conductive material, which may occur before or after the first portion of the conductive structures 450-452 is formed. In some embodiments, at least the second portion of the conductive structures 450-452 may also include liners 460-462 (e.g., as a barrier layer) formed around them, thereby separating them from the dielectric layer 440.

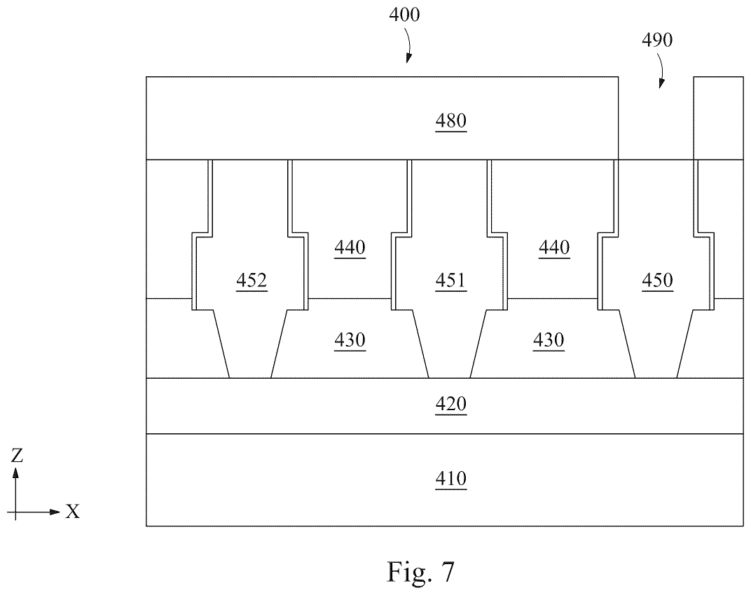

Referring now to FIG. 7, a patterned photoresist layer 480 is formed over the dielectric layer 440 and over the conductive structures 450-452. The patterned photoresist layer 480 may be formed by forming a photoresist material over the dielectric layer 440 and over the conductive structures 450-452 via a spin coating process, and then performing a lithography process to pattern the photoresist material. The lithography process may include an exposure step, a post-exposure bake step, a developing step, a post-developing step, etc. In some embodiments, a dielectric layer similar to the dielectric layer 370 (see FIG. 3) may also be formed under the patterned photoresist layer 480, where that dielectric layer may be patterned by the patterned photoresist layer 480. Regardless of whether such a dielectric layer is formed, the result is the formation of an opening 490 that is aligned with and that exposes the conductive structure 450. The rest of the conductive structures 451-452 are covered by the patterned photoresist layer 480.

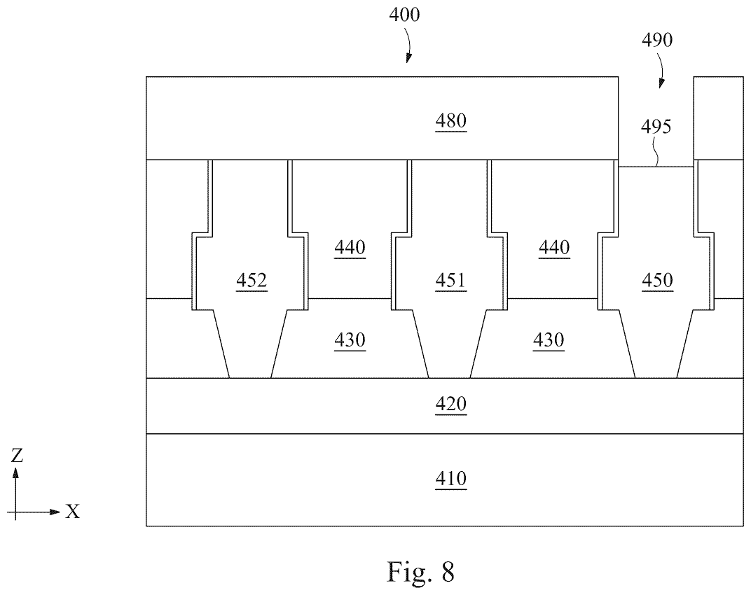

Referring now to FIG. 8, an etch back process is performed to the conductive structure 450. The patterned photoresist layer 480 (or the dielectric layer, if one is formed below the patterned photoresist layer 480) may serve as a protective mask while the etch back process is performed. As a result of the etch back process, a top portion of the conductive structure 450 is removed, and the conductive structure 450 is now recessed compared to the conductive structures 451-452. For example, an upper surface 495 of the conductive structure 450 is now located below (or has a lower vertical elevation) than the upper surfaces of the conductive structures 451-452. It is understood that although the upper surface 495 of the conductive structure 450 is illustrated as being relatively flat in FIG. 8, this is not required unless otherwise claimed. In various embodiments, the upper surface 495 itself may be formed to have a concave shape in the cross-sectional side view, for example, a curved concave shape, where the middle portion of the upper surface 495 has a lower vertical elevation and edge portions of the upper surface 495.

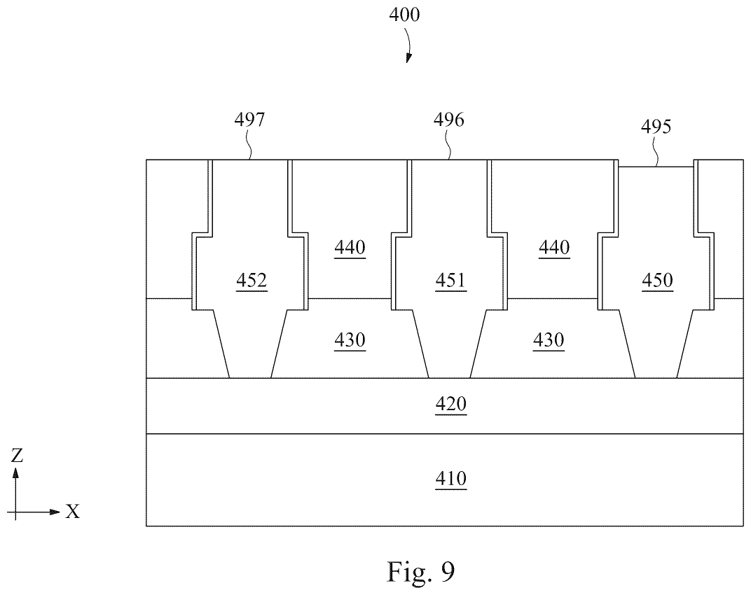

Referring now to FIG. 9, the patterned photoresist layer 480 is removed, for example, via a photoresist stripping or a photoresist ashing process. Alternatively, the patterned photoresist layer 480 may have been removed before the etch back process of FIG. 8, for example, in embodiments where the dielectric layer is formed below the patterned photoresist layer 480. In these embodiments, the dielectric layer may be removed after the etch back process of FIG. 8 is performed. In any case, after the removal of the patterned photoresist layer 480 and after the etching back of the conductive structure 450, the upper surfaces 495, 496, and 497 of the conductive structures 450, 451, and 452, respectively, are exposed. As discussed above, the upper surface 495 is located below, or has a lower vertical elevation, than the upper surfaces 496 and 497.

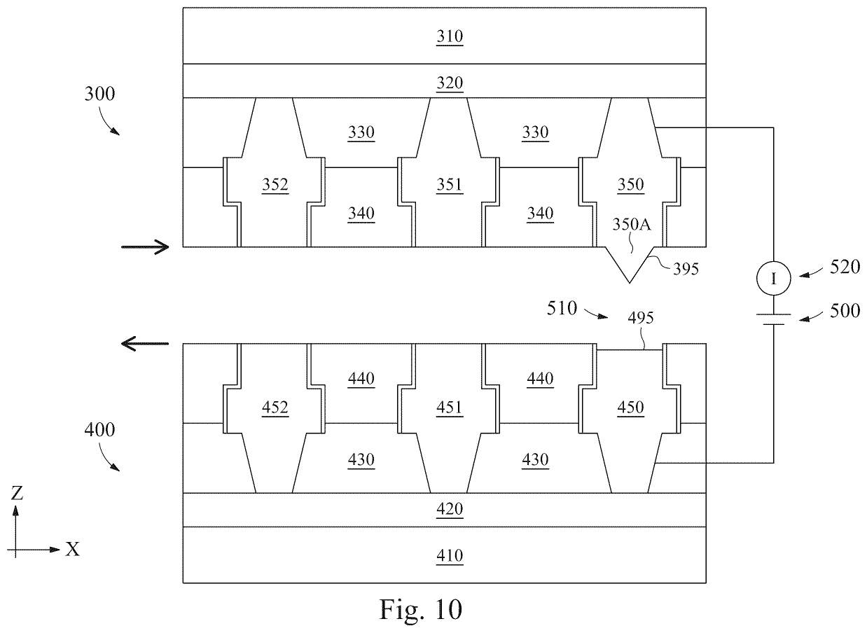

Referring now to FIG. 10, the IC structure 300 and the IC structure 400 are roughly aligned in an effort to prepare them for bonding. For example, the IC structure 300 is flipped vertically upside down in the Z-direction, such that the protruding portion 350A is facing against the recessed upper surface 495 of the conductive structure 450. However, in some embodiments, the protruding portion 350A and the recessed upper surface 495 may not come into physical contact with one another yet. In other words, an air gap 510 may exist between the conductive structures 350 and 450 at this point.

Meanwhile, a voltage source 500 may be used to apply an electrical vias (e.g., in the form of a voltage potential) across the conductive structures 350 and 450. For example, a first electrical voltage may be applied to the conductive structure 350 through an interconnection structure located in the IC structure 300, while a second electrical voltage may be applied to the conductive structure 450 through an interconnection structure located in the IC structure 400, and the difference between the first electrical voltage and the second electrical voltage may form the electrical bias applied across the conductive structures 350 and 450 (including the air gap 510 in between).

An electrical sensor, such as a current sensor 520, may also be deployed to measure an amount of electrical current that is generated in response to the applied electrical bias. In some embodiments, the resulting electrical current is in the form of a tunneling current. In that regard, a tunneling current may be the result of electrons moving through a barrier that they would not be able to pass through in classical mechanics. However, since electrons have wavelike properties according to quantum physics, some electrons may be able to “tunnel” over the barrier, particularly if the barrier is sufficiently thin, so that an electrical current (i.e., the tunneling current)—albeit small—may still be generated by these electrons. As the barrier becomes thinner and thinner, the amount of the tunneling current may increase as well.

According to the setup in FIG. 10, the barrier discussed above may be due to the fact that the conductive structure 350 and the conductive structure 450 are physically separated from one another by the air gap 510 is disposed between the tip of the protruding portion 350A of the conductive structure 350 and the upper surface 495 of the conductive structure 450. In some embodiments, the air gap 510 may have a size in the range of about 0.1 nanometers (nm) and about 20 nm in some embodiments.

To determine the optimal alignment position, the relative lateral positions (e.g., in the X-direction) of one of the IC structures 300 and 400 is shifted with respect to the other, while the electrical bias is applied by the voltage source 500, and while the resulting tunneling current is measured by the current sensor 520. It is understood that the shifting of the relative lateral positions between the IC structures 300 and 400 may be performed not just in the X-direction, but also in a Y-direction, which is a different horizontal direction that is orthogonal to the X-Z vertical plane defined by the X-direction and the Z-direction. For example, the shifting of the relative lateral positions between the IC structures 300 and 400 may first be performed in the X-direction, and then it may be performed in the Y-direction, or vice versa.

As the alignment between the IC structures 300 and 400 improves, the air gap 510 may shrink, which reduces the barrier for the tunneling current, and which in turn causes a greater amount of the tunneling current to be generated as a result. This is illustrated more visually in FIG. 10, which is a graph 550 of a relationship between the tunneling current and the alignment of the IC structures 300 and 400.

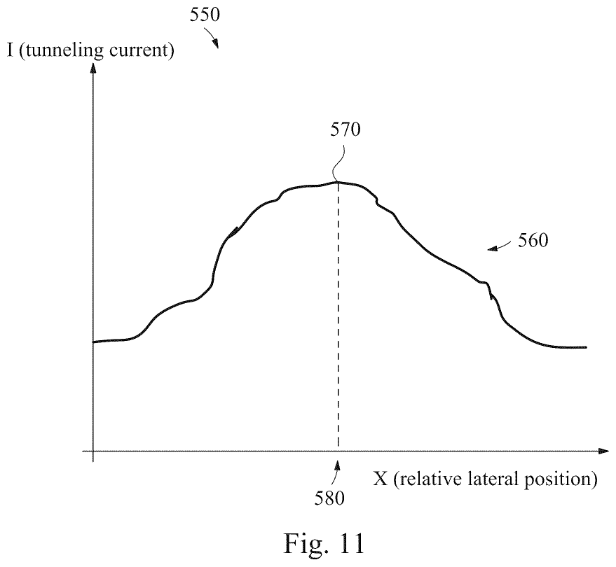

Referring to FIG. 11, the graph 550 is illustrated with respect to a horizontal axis X and a vertical axis I. The horizontal axis X represents a relative lateral position between the IC structures 300 and 400. As such, when the lateral position of one of the IC structures 300 and 400 is shifted with respect to the other one of the IC structures 300 and 400, the value on the horizontal axis X will change. Again, the lateral positions between the IC structures 300 and 400 may be shifted in a single horizontal direction (e.g., in just the X-direction) in some embodiments, or it may be shifted in two different horizontal directions (e.g., in both the X-direction and the Y-direction) in other embodiments. Meanwhile, the vertical axis I represents an amount (e.g., amplitude) of the tunneling current measured by the current sensor 520 at any corresponding relative lateral position on the horizontal axis X. Hence, the recording of the amplitude of the tunneling current measured by the current sensor 520 across a plurality of relative lateral positions between the IC structures 300 and 400 may be used to generate a plot 560.

As shown in FIG. 11, the shape of the plot 560 indicates that, when the value on the horizontal X axis is small, the value of the amplitude of the tunneling current may be relatively small, which indicates that the IC structures 300 and 400 have not reached optimal alignment. As the value on the horizontal X axis increases, the value of the amplitude of the tunneling current may gradually increase as well, which indicates that alignment between the IC structures 300 and 400 is gradually improving. At some point, the tunneling current reaches a maximum amplitude 570, which corresponds to a particular relative lateral position 580 on the horizontal axis X. Afterwards, the plot 560 shows that the tunneling current continues to decline as the relative lateral position on the horizontal axis X moves past the particular relative lateral position 580. Again, the particular relative lateral position 580 may include a component in the X-direction and another component in the Y-direction.

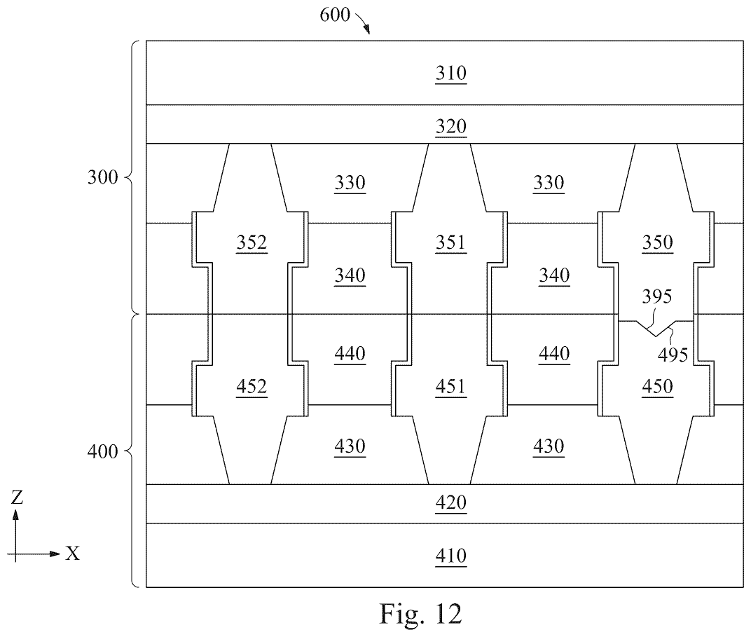

Based on the plot 560, it may be determined that the IC structures 300 and 400 reaches optimal alignment at the particular relative lateral position 580 between the IC structures 300 and 400. Accordingly, the IC structures 300 and 400 should be bonded together while they are aligned at the particular relative lateral position 580. A resulting IC structure 600 (e.g., as a result of the IC structures 300 and 400 being bonded together) is illustrated in FIG. 12, where the conductive structures 350 and 450 are bonded together, as are the conductive structures 351 and 451, as well as the conductive structures 352 and 452. For example, the surface 395 of the conductive structure 350 now extends to the surface 495 of the IC structure 450. For example, the surface 395 of the conductive structure 350 may be in direct or physical contact with the surface 495 of the IC structure 450.

It is understood that the material compositions of the conductive structures 350 and 450 may be configured differently than the material compositions of the conductive structures 351-352 and/or 451-452, in order to facilitate the alignment scheme discussed above. For example, in some embodiments, the conductive structure 350 and/or the conductive structure 450 may be configured to include a material with a greater conductivity (or lower resistivity) than the conductive structures 351-352 and/or the conductive structures 451-452. This may allow the tunneling current discussed above to be generated more easily and/or be detected more easily, which may facilitate the detection of the greatest amplitude of the tunneling current and the corresponding optimal alignment position between the conductive structures 350 and 450.

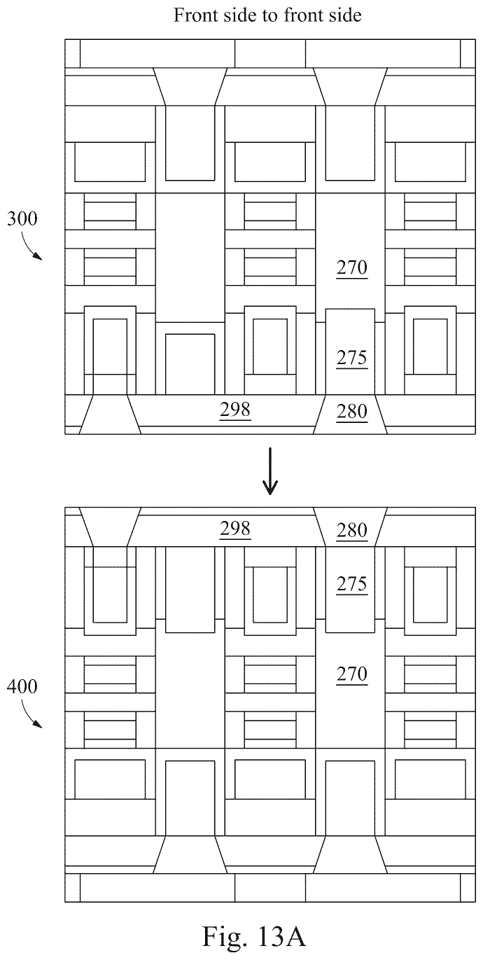

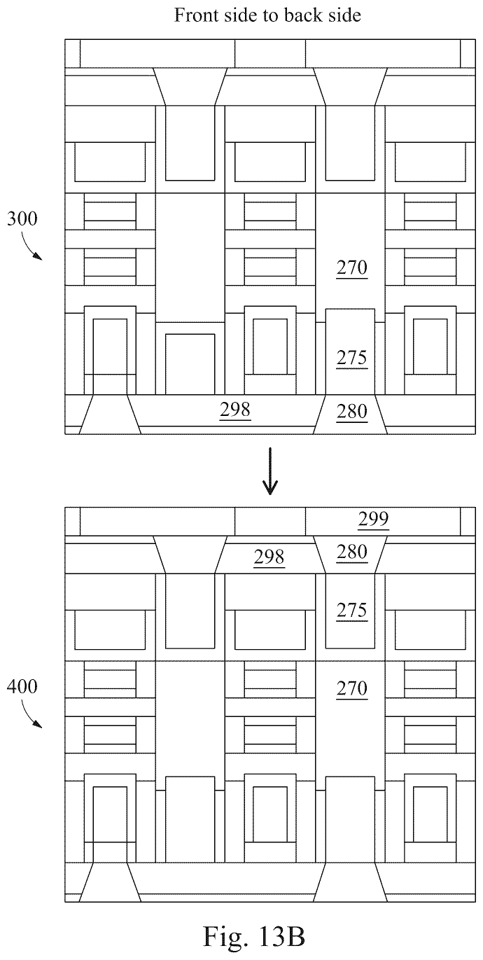

It is understood that the bonding herein is different from a chip-to-chip bonding scheme that takes place on a packaging level. For example, in the chip-to-chip bonding scheme on a packaging level, there are multiple middle-end-of-line (MEOL) and back-end-of-line (BEOL) connection structures between the bonded chips. In contrast, according to the CFET bonding scheme of the present disclosure, there are not any BEOL structures between the bonded IC structures. Furthermore, according to the CFET bonding scheme herein, a source/drain component of a top tier transistor of the CFET may be electrically coupled to a source/drain component of a bottom tier transistor of the CFET. This is illustrated in more detail in FIGS. 13A-13B.

Specifically, FIGS. 13A and 13B illustrates different types of bonding architectures or bonding schemes enabled by the present disclosure. For example, FIG. 13A illustrates a front-side-to-front-side architecture according to an embodiment of the CFET bonding scheme herein, where a front side of the IC structure 300 is bonded to a front side of the IC structure 400. In that regard, the bottom side of the IC structure 300 of FIG. 1D may be considered a front side, and the top side of the IC structure 300 of FIG. 1D may be considered a back side. As discussed above, the CFET bonding scheme herein (which is different from a chip-to-chip bonding scheme on a packaging level) allows the source/drain region 270 of the IC structure 300 (e.g., as the top tier device) to be electrically coupled to the source/drain region 270 of the IC structure 400 (e.g., as the bottom tier device) through the source/drain contacts 275 and the conductive vias 280 of the IC structures 300 and 400, respectively. In addition, the dielectric layers 298 of the IC structures 300 and 400 are bonded together in this CFET bonding scheme, as opposed to a much more complex BEOL connection structure bonded between the IC chips bonded together using a chip-to-chip scheme at the packaging level.

In another embodiment of the CFET bonding scheme, FIG. 13B illustrates a front-side-to-back-side architecture, where the front side of the IC structure 300 is bonded to the back side of the IC structure 400. Similar to the front-side-to-front-side architecture, the front-side-to-back-side architecture also allows the source/drain region 270 of the IC structure 300 (e.g., as the top tier device) to be electrically coupled to the source/drain region 270 of the IC structure 400 (e.g., as the bottom tier device) through the source/drain contacts 275 and the conductive vias 280 of the IC structures 300 and 400, respectively. One difference is that the front-side-to-back-side architecture shown in FIG. 13B also utilizes a bonding pad 299 to electrically connect the conductive vias 280 of the IC structures 300 and 400 together. For example, the top surface of the bonding pad 299 may be bonded to the bottom surface of the conductive via 280 of the IC structure 300, which then allows an electrical connection between the conductive via 280 of the IC structure 300 and the conductive via 280 of the IC structure 400. The implementation of the bonding pad 299 also enhances a margin for alignment, since the bonding pad 299 is wider than the conductive vias 280, thereby allowing a greater degree of horizontal shift between the IC structures 300 and 400 while still achieving the appropriate electrical connections after they are bonded together. The front-side-to-back-side CFET bonding scheme also eliminates the BEOL connection structure between the IC chips bonded together using a chip-to-chip scheme at the packaging level.

Again, it is understood that although the IC structure 300 and the IC structure 400 may be implemented as complementary field effect transistors (CFETs) that could be bonded together, the bonding alignment scheme herein may be utilized to determine the optimal alignment positions for other types of IC structures (e.g., non-CFET devices) that need to be bonded together.

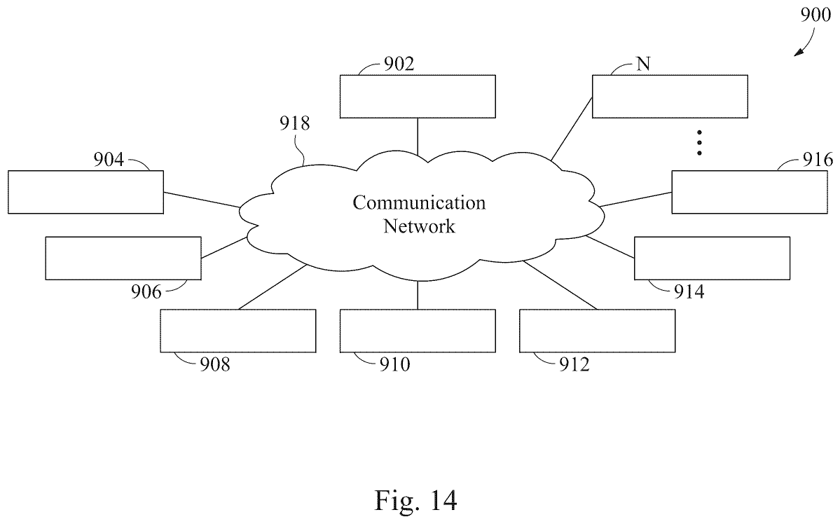

FIG. 14 illustrates an integrated circuit fabrication system 900 that may be used to perform the fabrication processes discussed above with reference to FIGS. 1-11, and/or to fabricate the CFET, according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes or a bonding tool for bonding different IC structures together; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

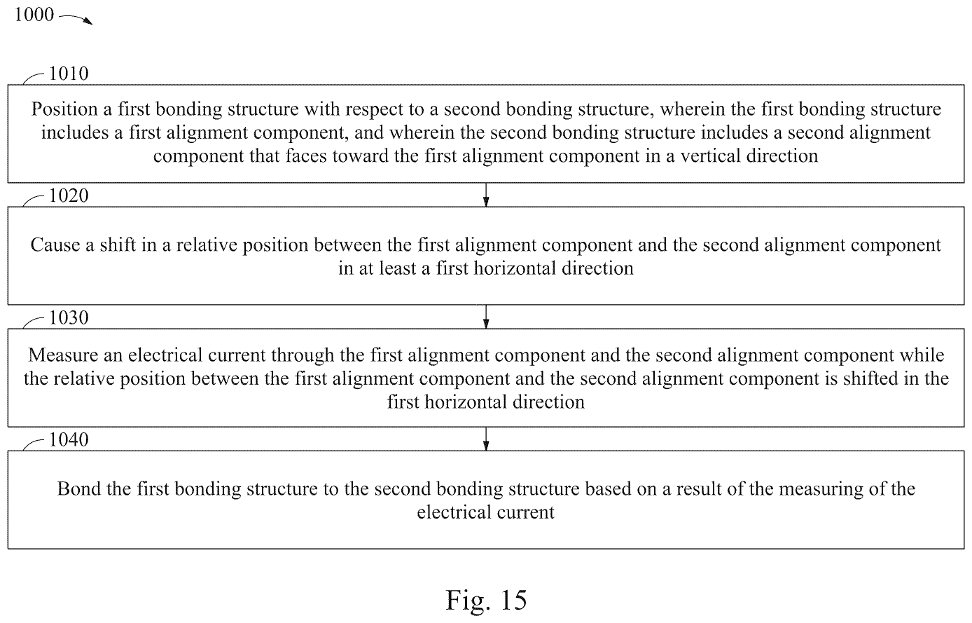

FIG. 15 is a flowchart of a method 1000 of bonding IC devices according to various aspects of the present disclosure. The method 1000 includes a step 1010 to position a first bonding structure with respect to a second bonding structure. The first bonding structure includes a first alignment component, and the second bonding structure includes a second alignment component that faces toward the first alignment component in a vertical direction.

The method 1000 includes a step 1020 to cause a shift in a relative position between the first alignment component and the second alignment component in at least a first horizontal direction.

The method 1000 includes a step 1030 to measure an electrical current through the first alignment component and the second alignment component while the relative position between the first alignment component and the second alignment component is shifted in the first horizontal direction.

The method 1000 includes a step 1040 to bond the first bonding structure to the second bonding structure based on a result of the measuring of the electrical current.

In some embodiments, the measuring of the step 1030 indicates that a maximum amplitude of the electrical current occurs at a particular relative position between the first alignment component and the second alignment component, and the bonding of the step 1040 is performed at the particular relative position between the first alignment component and the second alignment component. In some embodiments, the step 1020 further comprises causing the shift in the relative position between the first alignment component and the second alignment component in both the first horizontal direction and a second horizontal direction different from the first horizontal direction. The maximum amplitude of the electrical current occurs when the first alignment component and the second alignment component are at a first particular relative position in the first horizontal direction and at a second particular relative position in the second horizontal direction. The bonding of the step 1040 is performed when the first alignment component and the second alignment component are at the first particular relative position in the first horizontal direction and at the second particular relative position in the second horizontal direction.

In some embodiments, the electrical current is measured in step 1030 without the first alignment component making physical contact with the second alignment component. In some embodiments, a voltage vias is applied to the first alignment component and the second alignment component, and the electrical current includes a tunneling current generated in response to the applied voltage bias.

It is understood that the method 1000 may include additional steps that may be performed before, during, or after the steps 1010-1040. For example, in some embodiments, the following steps may be performed before the positioning of step 1010: a patterned mask layer is formed over the first bonding structure, the patterned mask layer including an opening that exposes the first alignment component; a conductive material is deposited on the first alignment component through the opening; an etch back process is performed to the deposited conductive material, thereby causing the deposited conductive material to have a protruding profile in a cross-sectional side view; and the patterned mask layer is removed after the etch back process has been performed.

As another example, in some embodiments, the following steps may be performed before the positioning of step 1010: a patterned mask layer is formed over the second bonding structure, the patterned mask layer including an opening that exposes the second alignment component; the second alignment component is etched back while the patterned mask layer serves as a protective mask, such that the second alignment component is recessed relative to a rest of the second bonding structure in a cross-sectional side view.

As yet another example, the following steps may be performed before the positioning of step 1010: the first bonding structure is formed over a first device; and the second bonding structure is formed over a second device. In some embodiments, the first device is a top device of a complementary field effect transistor (CFET), and the second device is a bottom device of the CFET. In some embodiments, the first bonding structure is formed to include a plurality of first conductive vias that extend vertically through a first dielectric layer in a cross-sectional side view, the first alignment component is one of the first conductive vias, at least a subset of the first conductive vias are electrically coupled to components of the first device, the second bonding structure is formed to include a plurality of second conductive vias that extend vertically through a second dielectric layer in the cross-sectional side view, the second alignment component is one of the second conductive vias, and at least a subset of the second conductive vias are electrically coupled to components of the second device. In some embodiments, the first bonding structure is formed such that the first alignment component has a different material composition than a rest of the first conductive vias, or the second bonding structure is formed such that the second alignment component has a different material composition than a rest of the second conductive vias. In some embodiments, the first bonding structure is formed such that the first alignment component has a greater electrical conductivity than the rest of the first conductive vias, or the second bonding structure is formed such that the second alignment component has a greater electrical conductivity than the rest of the second conductive vias.

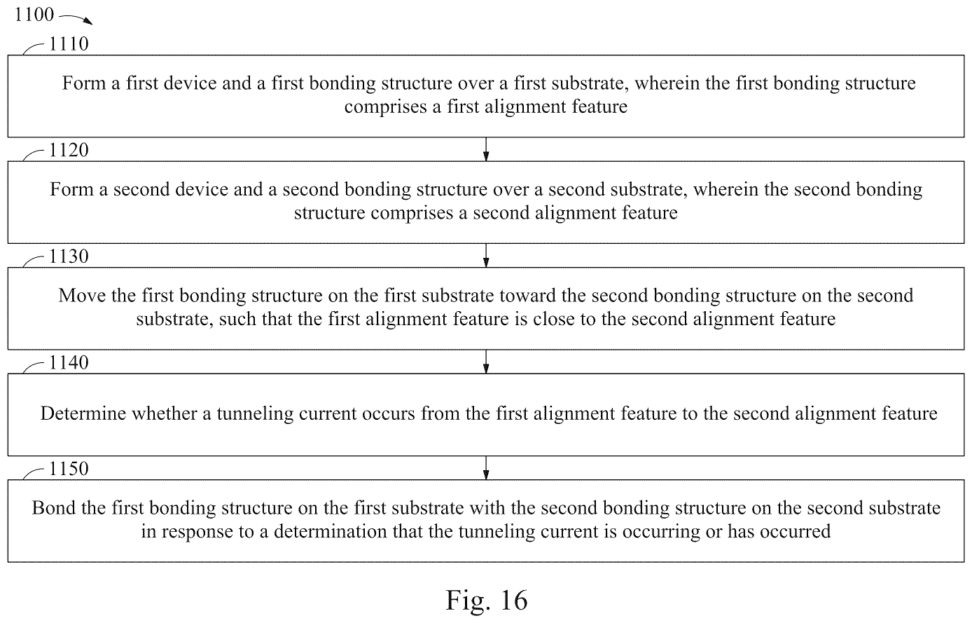

FIG. 16 is a flowchart of a method 1100 of bonding IC devices according to various aspects of the present disclosure. The method 1100 includes a step 1110 to form a first device and a first bonding structure over a first substrate. The first bonding structure comprises a first alignment feature.

The method 1100 includes a step 1120 to form a second device and a second bonding structure over a second substrate. The second bonding structure comprises a second alignment feature.

The method 1100 includes a step 1130 to move the first bonding structure on the first substrate toward the second bonding structure on the second substrate, such that the first alignment feature is close to the second alignment feature.

The method 1100 includes a step 1140 to determine whether a tunneling current occurs from the first alignment feature to the second alignment feature.

The method 1100 includes a step 1150 to bond the first bonding structure on the first substrate with the second bonding structure on the second substrate in response to the tunneling current being detected.

In some embodiments, the moving in step 1130 comprises positioning the first bonding structure with respect to the second bonding structure at various positions, the determining in step 1140 comprises measuring an amplitude of the tunneling current at each of the various positions, and the bonding in step 1150 is performed corresponding to a position of the various positions where a maximum amplitude of the tunneling current occurred.

In some embodiments, the forming the first device and the first bonding structure comprises forming the first alignment feature to have a convex tip, the forming the second device and the second bonding structure comprises forming the second alignment feature to have a concave recess, and the bonding is performed such that the convex tip of the first alignment feature extends to the concave recess of the second alignment feature.

In summary, the present disclosure involves a bonding alignment scheme. According to the scheme, a first conductive structure of a first IC structure (e.g., a top tier device of a CFET) and a second conductive structure of a second IC structure (e.g., a bottom tier device of the CFET) are positioned against each other, but without coming into physical contact with each other. An electrical bias (e.g., an electrical voltage potential) is then applied to the first and second conductive structures, and the resulting tunneling current running through the first and second IC structures is measured. The first IC structure and the second IC structure are then moved laterally with respect to one another, while the electrical bias is applied, and the resulting tunneling current is measured. When a maximum current amplitude of the tunneling current is detected, the corresponding relative lateral position between the first and second IC structures is recorded, and such a relative lateral position is deemed to be the optimal alignment position between the first and second IC structures. The bonding of the first and second IC structures may then be performed at such an optimal alignment position.

The embodiments of the present disclosure offer advantages over conventional CFET devices. It is understood, however, that other embodiments may offer additional advantages, and not all advantages are necessarily disclosed herein, and that no particular advantage is required for all embodiments. One advantage is the improved bonding alignment between different IC structures that need to be bonded together. Conventional techniques for aligning two different IC structures may involve using optical lenses and/or alignment keys to align the different IC structures. However, such a technique may be overly crude and may product an excessive overlay error, for example, an overlay error greater than about 50 nanometers. As IC devices continue to shrink, such an overlay error may become unacceptable, and the IC structures bonded together using such schemes may have poor device performance and/or even device failures. In contrast, the present disclosure utilizes the generation and measurement of a tunneling current to determine the optimal alignment position between the different IC structures. The amplitude of the tunneling current is an accurate indicator of alignment positions, because such an amplitude is correlated with positional offsets between the different IC structures. That is, the closer the two IC structures come into alignment, the greater the amplitude of the resulting tunneling current. In this manner, the present disclosure can product an alignment overlay error that is less than about 10 nanometers, which may lead to improved device performance and/or yield. Other advantages include compatibility with existing fabrication processes and the ease and low cost of implementation.

One aspect of the present disclosure pertains to a method. According to the method, a first bonding structure is positioned with respect to a second bonding structure. The first bonding structure includes a first alignment component. The second bonding structure includes a second alignment component that faces toward the first alignment component in a vertical direction. A relative position between the first alignment component and the second alignment component is shifted in at least a first horizontal direction while the first alignment component and the second alignment component. An electrical current is measured through the first alignment component and the second alignment component while the relative position between the first alignment component and the second alignment component is shifted in the first horizontal direction. The first bonding structure is bonded to the second bonding structure based on a result of the measuring of the electrical current.

Another aspect of the present disclosure pertains to a method. A first device and a first bonding structure area formed over a first substrate. The first bonding structure comprises a first alignment feature. A second device and a second bonding structure are formed over a second substrate. The second bonding structure comprises a second alignment feature. The first bonding structure on the first substrate is moved toward the second bonding structure on the second substrate, such that the first alignment feature is close to the second alignment feature. A determination is made as to whether a tunneling current occurs from the first alignment feature to the second alignment feature. The first bonding structure on the first substrate is bonded with the second bonding structure on the second substrate in response to a determination that the tunneling current is occurring or has occurred.

Yet another aspect of the present disclosure pertains to a device. The device includes a first device that includes a plurality of first transistors. The device includes a first bonding structure disposed over the first device. The first bonding structure includes a first dielectric layer and a first alignment component that extends vertically through the first dielectric layer in a cross-sectional side view. A surface of the first alignment component protrudes out of the first dielectric layer in the cross-sectional side view. The device includes a second device that includes a plurality of second transistors. The device includes a second bonding structure disposed over the second device. The second bonding structure includes a second dielectric layer and a second alignment component that extends vertically through the second dielectric layer in the cross-sectional side view. A surface of the second alignment component is recessed relative to a surface of the second dielectric layer in the cross-sectional side view. The first bonding structure is bonded to the second bonding structure such that the surface of the first alignment component is in physical contact with the surface of the second alignment component.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
positioning a first bonding structure with respect to a second bonding structure, wherein the first bonding structure includes a first alignment component, and wherein the second bonding structure includes a second alignment component that faces toward the first alignment component in a vertical direction;
causing a shift in a relative position between the first alignment component and the second alignment component in at least a first horizontal direction;
measuring an electrical current through the first alignment component and the second alignment component while the relative position between the first alignment component and the second alignment component is shifted in the first horizontal direction; and
bonding the first bonding structure to the second bonding structure based on a result of the measuring of the electrical current.

2. The method of claim 1, wherein:
the measuring indicates that a maximum amplitude of the electrical current occurs at a particular relative position between the first alignment component and the second alignment component; and
the bonding is performed at the particular relative position between the first alignment component and the second alignment component.

3. The method of claim 2, wherein:
the causing further comprises causing the shift in the relative position between the first alignment component and the second alignment component in both the first horizontal direction and a second horizontal direction different from the first horizontal direction; the maximum amplitude of the electrical current occurs when the first alignment component and the second alignment component are at a first particular relative position in the first horizontal direction and at a second particular relative position in the second horizontal direction; and
the bonding is performed when the first alignment component and the second alignment component are at the first particular relative position in the first horizontal direction and at the second particular relative position in the second horizontal direction.

4. The method of claim 1, wherein the electrical current is measured without the first alignment component making physical contact with the second alignment component.

5. The method of claim 1, further comprising applying a voltage vias to the first alignment component and the second alignment component, wherein the electrical current includes a tunneling current generated in response to the applied voltage bias.

6. The method of claim 1, further comprising, before the positioning:
forming a patterned mask layer over the first bonding structure, the patterned mask layer including an opening that exposes the first alignment component;
depositing a conductive material on the first alignment component through the opening;
performing an etch back process to the deposited conductive material, thereby causing the deposited conductive material to have a protruding profile in a cross-sectional side view; and
removing the patterned mask layer after the etch back process has been performed.

7. The method of claim 1, further comprising, before the positioning:
forming a patterned mask layer over the second bonding structure, the patterned mask layer including an opening that exposes the second alignment component; and
etching back the second alignment component while the patterned mask layer serves as a protective mask, such that the second alignment component is recessed relative to a rest of the second bonding structure in a cross-sectional side view.

8. The method of claim 1, further comprising, before the positioning:
forming the first bonding structure over a first device; and
forming the second bonding structure over a second device;
wherein:
the first device is a top device of a complementary field effect transistor (CFET); and
the second device is a bottom device of the CFET.

9. The method of claim 8, wherein:
the top device includes a first source/drain component;
the bottom device includes a second source/drain component; and
the bonding is performed at least in part by electrically coupling the first source/drain component and the second source/drain component together.

10. The method of claim 8, wherein:
the first bonding structure is formed to include a plurality of first conductive vias that extend vertically through a first dielectric layer in a cross-sectional side view;
the first alignment component is one of the first conductive vias;
at least a subset of the first conductive vias are electrically coupled to components of the first device;
the second bonding structure is formed to include a plurality of second conductive vias that extend vertically through a second dielectric layer in the cross-sectional side view;
the second alignment component is one of the second conductive vias; and
at least a subset of the second conductive vias are electrically coupled to components of the second device.

11. The method of claim 10, wherein:
the first bonding structure is formed such that the first alignment component has a different material composition than a rest of the first conductive vias; or
the second bonding structure is formed such that the second alignment component has a different material composition than a rest of the second conductive vias.

12. The method of claim 11, wherein:
the first bonding structure is formed such that the first alignment component has a greater electrical conductivity than the rest of the first conductive vias; or
the second bonding structure is formed such that the second alignment component has a greater electrical conductivity than the rest of the second conductive vias.

13. A method, comprising:
forming a first device and a first bonding structure over a first substrate, wherein the first bonding structure comprises a first alignment feature;
forming a second device and a second bonding structure over a second substrate, wherein the second bonding structure comprises a second alignment feature;
moving the first bonding structure on the first substrate toward the second bonding structure on the second substrate, such that the first alignment feature is close to the second alignment feature;
determining whether a tunneling current occurs from the first alignment feature to the second alignment feature; and
bonding the first bonding structure on the first substrate with the second bonding structure on the second substrate in response to a determination that the tunneling current is occurring or has occurred.

14. The method of claim 13, wherein:
the moving comprises positioning the first bonding structure with respect to the second bonding structure at various positions;
the determining comprises measuring an amplitude of the tunneling current at each of the various positions; and
the bonding is performed corresponding to a position of the various positions where a maximum amplitude of the tunneling current occurred.

15. The method of claim 13, wherein:
the forming the first device and the first bonding structure comprises forming the first alignment feature to have a convex tip;
the forming the second device and the second bonding structure comprises forming the second alignment feature to have a concave recess; and
the bonding is performed such that the convex tip of the first alignment feature is in physical contact with the concave recess of the second alignment feature.

16. A device, comprising:
a first device that includes a plurality of first transistors;
a first bonding structure disposed over the first device, wherein the first bonding structure includes a first dielectric layer and a first alignment component that extends vertically through the first dielectric layer in a cross-sectional side view, and wherein a surface of the first alignment component protrudes out of the first dielectric layer in the cross-sectional side view;
a second device that includes a plurality of second transistors; and
a second bonding structure disposed over the second device, wherein the second bonding structure includes a second dielectric layer and a second alignment component that extends vertically through the second dielectric layer in the cross-sectional side view, wherein a surface of the second alignment component is recessed relative to a surface of the second dielectric layer in the cross-sectional side view, and wherein the first bonding structure is bonded to the second bonding structure such that the surface of the first alignment component extends to the surface of the second alignment component.

17. The device of claim 16, wherein:
the first bonding structure further includes a plurality of first conductive vias that each extend vertically through the first dielectric layer;
the first conductive vias provide electrical connectivity to the first transistors of the first device;
the second bonding structure further includes a plurality of second conductive vias that each extend vertically through the second dielectric layer;
the second conductive vias provide electrical connectivity to the second transistors of the second device; and
each of the first conductive vias is bonded to a respective one of the second conductive vias.

18. The device of claim 17, wherein:
the first alignment component has a different material composition than the first conductive vias; or
the second alignment component has a different material composition than the second conductive vias.

19. The device of claim 18, wherein:
the first alignment component has a greater electrical conductivity than the first conductive vias; or
the second alignment component has a greater electrical conductivity than the second conductive vias.

20. The device of claim 16, wherein:
one of the first device and the second device is a top device of a complementary field effect transistor (CFET), and another one of the first device and the second device is a bottom device of the CFET;
the top device includes a first source/drain component, a first source/drain contact electrically connected to the first source/drain component, and a first conductive via electrically connected to the first source/drain contact;
the bottom device includes a second source/drain component, a second source/drain contact electrically connected to the second source/drain component, and a second conductive via electrically connected to the second source/drain contact; and
the first conductive via is bonded to the second conductive via.
